(19) United States
(12) Patent Application Publication
(10) Pub. No.: US 2011/0086500 A1
(43) Pub. Date: Apr. 14, 2011

(54) IMPURITY IMPLANTATION METHOD AND ION IMPLANTATION APPARATUS

(76) Inventors: Kenji Yoneda, Kyoto (JP); Hiroko Kubo, Kyoto (JP)

(21) Appl. No.: 12/842,616

(22) Filed: Jul. 23, 2010

(30) Foreign Application Priority Data
Oct. 13, 2009 (JP) 2009-235880

(51) Int. Cl. H01L 21/266; G21K 1/08

(52) U.S. Cl. 438/514; 250/396 R; 250/397; 257/E21.346

(57) ABSTRACT

An impurity is implanted by ion implantation into an object to be processed. The ion implantation is performed using an ion beam which is diverged after being temporarily converged.

### CROSS-REFERENCE TO RELATED APPLICATION

This application claims priority to Japanese Patent Application No. 2009-235880 filed on Oct. 13, 2009, the disclosure of which including the specification, the drawings, and the claims is hereby incorporated by reference in its entirety.

### BACKGROUND

The present disclosure relates to impurity implantation methods and ion implantation apparatuses for use in processes of fabricating semiconductor devices, particularly a process of selectively implanting an impurity into a deep region of a semiconductor substrate.

In recent years, there is an increasing necessity to form an impurity layer deep below the silicon substrate surface in semiconductor integrated circuit devices, particularly solid-state imaging devices, such as charge coupled devices (CCDs), complementary metal oxide semiconductor (CMOS) sensors, and the like, or high breakdown voltage devices, such as insulated gate bipolar transistors (IGBTs) and the like.

In order to introduce an impurity into such a deep position, a drive-in technique including introduction of the impurity into a semiconductor surface portion and a subsequent thermal treatment at high temperature and for a long time has ever been used. In recent years, a technique is used which selectively forms an impurity diffusion layer at a deep portion of a semiconductor substrate by implanting ions having high energy using a thick photoresist film or hard mask.

For example, Japanese Patent Publication No. 2008-235753 describes a solid-state imaging device in which ultra-high energy ion implantation is performed with respect to all pixels to form a potential, and high energy ion implantation is performed with respect to photodiodes for red (R), green (G), and blue (B) using resist masks.

In particular, considering that light having a relatively long wavelength corresponding to R reaches a deeper position in the semiconductor substrate, it can be readily understood that it is necessary to implant ions into a deeper position, i.e., with higher energy in order to improve the sensitivity of the photodiode for R.

Also, for example, Japanese Patent Publication No. H08-17848 describes a method for fabricating an IGBT in which, particularly because lateral extension of an impurity diffusion region hinders microfabrication of the device, high energy implantation and controlled thermal diffusion are used to form an impurity layer having less lateral extension in a deep region.

Thus, it is one of the most important techniques to form a deep impurity diffusion layer with less lateral extension by introducing an impurity into a deep portion of the semiconductor substrate by high energy implantation and using a resist or the like as a mask and thereafter performing a minimum thermal treatment.

### SUMMARY

However, when the aforementioned conventional technique of selectively performing high energy ion implantation using a resist mask is carried out, the following various problems arise.

For example, Japanese Patent Publication No. 2003-248293 describes a technique of forming a fine opening pattern in a thick resist which is used as a mask for high energy ion implantation. Specifically, Japanese Patent Publication No. 2003-248293 describes that a resist needs to have a thickness of 5.5 μm when the acceleration energy of ion (boron (B)) implantation is 3 MeV, and a fine pattern having a feature dimension of 1 μm or less needs to be formed in such a thick resist.

In recent years, it is not rare to employ 5-MeV ion (B) implantation. Boron ions which are accelerated at 3 MeV have an Rp (average range) of 3.83 μm and a ΔRp (1σ of Rp) of 0.2134 μm. Therefore, as a mask for 3-MeV ion (B) implantation, a resist having a thickness of at least about 5.5 μm is required. Boron ions which are accelerated at 5 MeV have an average range Rp of 5.96 μm and a ΔRp (1σ) of 0.2638 μm. Therefore, as a mask for 5-MeV ion (B) implantation, a resist having a thickness of at least about 8 μm is required.

Also, for example, Japanese Patent Publication No. H06-204162 describes that when high energy ion implantation is performed, a resist pattern shape, particularly a sloped foot of a skirt portion (sloped resist), causes a problem, and proposes a resist material which does not cause the sloped shape.

Specifically, Japanese Patent Publication No. H06-204162 describes that when high energy ion implantation is performed, then if the sidewall of the resist pattern is not vertical, ions are hindered from reaching an intended depth by the non-vertical sidewall or sloped foot of the resist pattern.

FIG. 7 is a cross-sectional view schematically showing ion implantation which is performed in a direction normal to a silicon substrate using a resist mask having an opening for ion implantation, where the opening has a tapered sidewall. As shown in FIG. 7, the resist mask 62 having the opening 65 with the tapered sidewall is formed on the silicon substrate 61. The ion implantation 63 is being performed using the resist mask 62 with high energy in a direction normal to the silicon substrate 61. Ions introduced through the opening 65 into the silicon substrate 61 are distributed around a predetermined Rp and are also laterally distributed across an extension close to ΔRp. The distributed ions form a normal implanted region 66. On other hand, as shown in FIG. 7, when the resist mask 62 has a tapered sidewall portion 64, ions entering the sidewall portion 64 are hindered from traveling by the resist mask 62. As a result, the ions are implanted into a portion of the silicon substrate 61 shallower than the portion of the silicon substrate 61 into which ions are introduced through the opening 65. The ions also laterally spread to a larger extent than in the normal implanted region 66, resulting in a shallow and wide implanted region 67. The implanted region 67 is not desirable. Thus, when high energy ion implantation is performed, the sloped resist (sloped resist pattern) is also problematic.

Moreover, because a resist which is used as a mask for high energy ion implantation has a large thickness as described above, even when the resist pattern has a vertical sidewall, then if there are variations in the incident direction of ions in ion implantation, the ions are so widely distributed at a deep position in the semiconductor substrate that a predetermined characteristic cannot be obtained, which is a problem.

FIG. 8 is a cross-sectional view schematically showing ion implantation which is performed using a resist mask having an opening for ion implantation, where the sidewall of the opening is vertical and there are variations in the incident direction of ions. As shown in FIG. 8, the resist pattern 72 having the opening 76 for ion implantation which has the vertical sidewall 75 is formed on a silicon substrate 71. The silicon substrate 71 is irradiated, using the resist pattern 72 as a mask, with an ion beam 73 with high energy in a direction normal to the silicon substrate 71. Here, the ion beam 73 has a beam divergence 74 having an angle of deviation of γ from a predetermined direction (the normal direction of the silicon substrate 71). Even if the resist pattern 72 has the vertical sidewall 75 of the opening 76 for ion implantation, i.e., the resist pattern 72 has a desired shape as described above, then if the ion beam 73 has the beam divergence 74, implanted ions are widely distributed in the silicon substrate 71. Specifically, the impurity implanted region includes a normal implanted region 77 formed in the vicinity of Rp and an implanted region 78 which is extended around the region 77 at a slightly shallower position. Here, ions which pass through the resist pattern 72 in the vicinity of the opening 76 and obliquely enter the silicon substrate 71 due to the deviation angle y of the ion beam 73, further laterally spread in the silicon substrate 71 to form an implanted region shallower than Rp. Note that most of ions constituting the ion beam 73 have incident angles distributed in the vicinity of the normal direction of the silicon substrate 71, i.e., only a minority of ions have the deviation angle. Therefore, the total number of ions in the implanted region 78 which is formed by the minority ions spreading in the silicon substrate 71 at a shallower position is not large. Nevertheless, the impurity diffusion layer has a non-negligible lateral extension and depth-direction extension. Note that, as shown in FIG. 8, the lateral extension is given by:

(T+Rp)×tan(γ)+ΔRp

where T is the thickness of the resist pattern 72.

In high energy ion implantation, a high energy ion beam is used. The beam, which has high convergence capability, may be a considerably sharp beam having a diameter of about 20 mm. As shown in FIG. 9, in ion implantation with respect to a wafer 81, irradiation with an ion beam 82 includes a fast scan 84 with a fast scan speed and a slow scan 85 with a slow scan speed. Here, the ion beam 82 is continuously scanned in the fast scan 84. However, because the scan speed of the slow scan 85 is slow, the ion implantation is performed as if the fast scan 84 were repeatedly performed on the wafer 81 at predetermined pitches (scan pitches) P (scan path 83). The scan pitch P is set so that a predetermined beam overlap 86 is provided.

Japanese Translation of PCT International Application No. 2008-522431 describes that, by modulating the speed of the fast scan by a beam shape (a beam current and a beam size), the efficiency of use of the beam is maximized for a predetermined dose and a predetermined uniformity. The speed of the slow scan has a value which is calculated from the speed of the fast scan. The slow scan determines the scan pitch of the beam. Because it is clear that no uniformity is obtained when the scan pitch P is larger than the beam size (here, 20 mm), the scan pitch is set to a value which can ensure the uniformity.

For example, there is a high energy ion implantation apparatus having a scan system which performs a fast scan by rotating, at a high speed, a disk on which a wafer is placed and a slow scan by moving the disk at a low speed while rotating the disk. Here, it is assumed that the radius of rotation between the center of the disk and the center of the wafer is 750 mm, and the rotational speed of the disk is 815 rpm (i.e., 13.6 Hz). In this case, the center portion of the wafer has a linear velocity of as high as 64 in/sec. On the other hand, for the slow scan, it is assumed that one round trip across a 300-mm wafer takes about 60 sec. In this case, the linear velocity is 1 cm/sec and the scan pitch is 1 cm/sec÷13.6 Hz=0.74 mm. Thus, the scan pitch is about 1/27 of the beam size.

Here, the uniformity of the ion beam scan is ensured under the assumption that the ion beam is a Gaussian beam. For example, when the overlap of the Gaussian beam is about 1/27 of the beam size, the dose after overlapping has an almost constant value. In other words, variations in the dose due to the overlapping of the Gaussian beam are typically negligibly small.

However, actual ion beams are not symmetrical Gaussian beams. In Japanese Translation of PCT International Application No. 2008-522431, the beam is assumed to have a parabolic shape. Specifically, Japanese Translation of PCT International Application No. 2008-522431 describes that the speed of the fast scan is modulated according to changes in the beam current and the beam size while the parabolic shape of the beam is maintained. However, the shape of the skirt portion of the beam, which is one of the most important parameters of the beam shape, is not taken into consideration. Therefore, when the beam scan pitch is not set to be sufficiently smaller than the beam size, the fluctuation in the dose due to the overlapping of the beam (beam overlapping) may become significant.

In the case of typical versions of ion implantation other than high energy ion implantation, after ion implantation the concentration of an implanted impurity is caused to be more uniform by diffusion using a thermal treatment. As described above, however, in the case of high energy ion implantation, after ion implantation a high-temperature and long-time thermal treatment which may eliminate the effect is not performed. In high energy ion implantation for fabrication of solid-state imaging devices or power devices, the dose is as low as 1×10¹³ cm⁻² or less, particularly 1×10¹² cm⁻² or less in some cases, and therefore, the fluctuation in the dose due to an insufficient beam overlap becomes significant. For example, the following problems occur. The impurity concentration distributions of a photodiode formed deep in a solid-state imaging device and a potential formation region formed immediately below the photodiode are parameters which determine the saturation characteristic of the solid-state imaging device. If a fluctuation occurs in the concentration distributions of these deep impurity diffusion layers, a difference in the saturation characteristic may appear as an image, or the photodiode may have a non-uniform sensitivity. Also, in high breakdown voltage power devices, variations in the breakdown voltage may occur.

In order to reduce the aforementioned variations in the impurity concentration distributions of the deep impurity diffusion layers, the scan pitch may be narrowed by reducing the scan speed in the slow scan direction. For example, if the speed of the slow scan is decreased by a factor of about 3, the scan pitch can be reduced from 0.74 mm to 0.28 mm. As a result, variations in the dose due to beam overlapping is decreased by a factor of about 3. In this case, however, as can be easily calculated, because the speed of the slow scan is decreased by a factor of 3, the time required for ion implantation increases by a factor of 3, i.e., the productivity is decreased by a factor of 3, which is a problem.

Here, when it is necessary to maintain the speed of the fast scan irrespective of the decrease in the speed of the slow scan, the beam current may be decreased by a factor of 3. Although the speed of the fast scan may be increased by a factor of 3 instead of decreasing the beam current by a factor of 3, when the fast scan is performed by rotating a disk as described above, it is difficult to increase the rotational speed by a factor of 3. On the other hand, to decrease the beam current also has the following difficulty. Specifically, because the dose of ion implantation is relatively low in the fabrication of solid-state imaging devices or high breakdown voltage power devices as described above, the ion beam easily converges, particularly when a high energy ion implantation apparatus is used, and therefore, it is often that the beam current cannot be reduced to a predetermined value or less.

Therefore, the method of reducing the speed of the slow scan to narrow the scan pitch in order to reduce variations in the impurity concentration distributions of the deep impurity diffusion layers, can be used only when the beam current can be further reduced.

In view of the aforementioned problems, the detailed description describes implementations of an impurity implantation method and an ion implantation apparatus capable of reducing variations in the dose, the implantation depth, and the like of high energy ion implantation due to a mismatch between the ion beam shape and the scan pitch, thereby providing a high-quality deep impurity layer in fabrication of solid-state imaging devices, high breakdown voltage power devices, and the like, without a decrease in the productivity.

An example method for implanting an impurity by ion implantation into an object to be processed, includes performing the ion implantation using an ion beam which is diverged after being temporarily converged.

According to the example impurity implantation method of the present disclosure, ion implantation is performed using an ion beam which is diverged after being temporarily converged. Therefore, a beam shape, particularly a beam skirt shape having a large influence on the uniformity, can be controlled according to the scan pitch of the ion beam. Specifically, for example, by diverging and broadening the ion beam, the uniformity of the implantation dose, the implantation depth, and the like can be improved without decreasing the scan pitch of the ion beam. Therefore, even when the ion implantation is performed with high energy and a low dose, the uniformity can be improved without sacrificing the productivity.

Therefore, by applying the example impurity implantation method of the present disclosure to formation of a deep well or photodiode of a solid-state imaging device, formation of a deep impurity diffusion layer of a high breakdown voltage device, and the like, non-uniform saturation, non-uniform sensitivity, and the like can be reduced in the solid-state imaging device, and variations in the breakdown voltage, and the like can be reduced in the high breakdown voltage device, i.e., the performance of these devices can be improved.

In the example impurity implantation method of the present disclosure, an implantation angle with respect to the object to be processed of ions in the diverged ion beam may be controlled to a predetermined angle. In this case, the extension of the impurity implanted region due to variations in the incident direction of ions in high energy ion implantation can be reduced.

In the example impurity implantation method of the present disclosure, the object to be processed may be a semiconductor substrate or a semiconductor layer, a pattern made of a photoresist or a hard mask and having an opening may be formed on the object to be processed, and the impurity may be implanted through the opening into the object to be processed. In this case, an impurity layer having small variations in the implantation dose, the implantation depth, and the like can be reliably formed at a deep position below a surface of the semiconductor substrate or the semiconductor layer.

In the example impurity implantation method of the present disclosure, the ion beam may be two-dimensionally scanned over the object to be processed. In this case, the ion beam may be scanned in a fast scan direction at a first scan speed, and may be scanned in a slow scan direction at a second scan speed lower than the first scan speed. The object to be processed may be placed on a rotating member. The first scan speed may be provided by rotation of the rotating member, and the second scan speed may be provided by reciprocal movement of the rotating member.

In the example impurity implantation method of the present disclosure, when the ion beam is scanned in the two directions, i.e., the fast scan direction and the slow scan direction, an intensity change rate at a position in a profile of an intensity of the ion beam where the intensity of the ion beam is 50% of a maximum intensity of the ion beam may be controlled to satisfy a relationship given by:

Ps<I max/S50

where Imax is the maximum intensity of the ion beam, S50 is the intensity change rate at the position of the ion beam, and Ps is a scan pitch in the slow scan direction.

In this case, by broadening the ion beam shape, the uniformity of the implantation dose, the implantation depth, and the like can be reliably improved without decreasing the scan pitch of the ion beam. In this case, the implantation angle with respect to the object to be processed of ions in the ion beam may be controlled to a predetermined angle over an entire region of the ion beam. In this case, the extension of the impurity implanted region due to variations in the incident direction of ions in high energy ion implantation can be reduced.

In the example impurity implantation method of the present disclosure, if the ion implantation is performed at an acceleration energy of 1 MeV or more, the aforementioned advantages can be reliably obtained compared to the conventional art.

In the example impurity implantation method of the present disclosure, if the ion beam is a spot beam, the aforementioned advantages can be reliably obtained compared to the conventional art.

As used herein, the term “spot beam” refers to a beam having a diameter which is about ⅕ or less of the diameter of the object to be processed by ion implantation, such as a wafer. Note that even when a “beam other than a spot beam,” such as a so-called ribbon (band-shaped) beam having, for example, a size which is larger than or equal to the diameter of the wafer in the fast scan direction and a size which is about 20 mm in the slow scan direction, is used rather than a spot beam, beam overlapping occurs in the slow scan direction, whereby the advantages of the present disclosure can be sufficiently obtained.

An example apparatus for implanting an impurity by ion implantation into an object to be processed, includes a defocusing unit including a converging lens configured to converge an ion beam and a diverging lens configured to diverge and expand the ion beam converged by the converging lens.

The example ion implantation apparatus of the present disclosure includes a defocusing unit including a converging lens configured to converge an ion beam and a diverging lens configured to diverge and expand the ion beam converged by the converging lens. Therefore, a beam shape, particularly a beam skirt shape having a large influence on the uniformity, can be controlled according to the scan pitch of the ion beam. Specifically, for example, by diverging and broadening the ion beam, the uniformity of the implantation dose, the implantation depth, and the like can be improved without decreasing the scan pitch of the ion beam. Therefore, even when the ion implantation is performed with high energy and a low dose, the uniformity can be improved without sacrificing the productivity.

Therefore, by applying the example ion implantation apparatus of the present disclosure to formation of a deep well or photodiode of a solid-state imaging device, formation of a deep impurity diffusion layer of a high breakdown voltage device, and the like, non-uniform saturation, non-uniform sensitivity, and the like can be reduced in the solid-state imaging device, and variations in the breakdown voltage, and the like can be reduced in the high breakdown voltage device, i.e., the performance of these devices can be improved.

In the example ion implantation apparatus of the present disclosure, the defocusing unit may further include a control lens configured to control an irradiation angle with respect to the object to be processed of ions in the ion beam expanded by the diverging lens. In this case, the extension of the impurity implanted region due to variations in the incident direction of ions in high energy ion implantation can be reduced. In this case, the control lens may be another converging lens.

The example ion implantation apparatus of the present disclosure may further include a beam profiler provided downstream from the defocusing unit and configured to measure a shape of the ion beam. In this case, by feeding information obtained by the beam profiler back to the defocusing unit, the ion beam shape can be reliably controlled.

The example ion implantation apparatus of the present disclosure may further include a mechanism configured to allow the ion beam to be two-dimensionally scanned over the object to be processed. In this case, the mechanism may allow the ion beam to be scanned in a fast scan direction at a first scan speed and to be scanned in a slow scan direction at a second scan speed lower than the first scan speed. The example ion implantation apparatus of the present disclosure may further include a beam profiler provided downstream from the defocusing unit and configured to measure a shape of the ion beam, including a skirt portion thereof, in the fast scan direction and in the slow scan direction. In this case, by feeding information obtained by the beam profiler back to the defocusing unit, the ion beam shape, particularly the beam skirt shape having a large influence on the uniformity, can be reliably controlled. Moreover, in this case, the mechanism may include a rotating member on which the object to be processed is placed. The first scan speed may be provided by rotation of the rotating member, and the second scan speed may be provided by reciprocal movement of the rotating member.

In the example ion implantation apparatus of the present disclosure, the ion implantation may be performed at an acceleration energy of 1 MeV or more. In this case, the aforementioned advantages can be reliably obtained compared to the conventional art.

In the example ion implantation apparatus of the present disclosure, the ion beam may be a spot beam. In this case, the aforementioned advantages can be reliably obtained compared to the conventional art.

As described above, according to the present disclosure, by controlling the ion beam shape, particularly the beam skirt shape having a large influence on the uniformity, according to the scan pitch, the uniformity of the implantation dose, the implantation depth, and the like can be improved without sacrificing the productivity even when ion implantation is performed with high energy and a low dose.

Therefore, by applying the present disclosure to formation of a deep well or photodiode of a solid-state imaging device, formation of a deep impurity diffusion layer of a high breakdown voltage device, and the like, non-uniform saturation, non-uniform sensitivity, and the like can be reduced in the solid-state imaging device, and variations in the breakdown voltage, and the like can be reduced in the high breakdown voltage device, i.e., the performance of these devices can be improved.

Thus, the present disclosure is useful for fabrication processes of semiconductor devices, particularly an impurity implantation method and an ion implantation apparatus for use in a process of selectively implanting an impurity into a region deep in the semiconductor substrate.

### BRIEF DESCRIPTION OF THE DRAWINGS

FIG. 1 is a cross-sectional diagram schematically showing a structure of an example solid-state imaging device to which an impurity implantation method according to an embodiment of the present disclosure is applied.

FIG. 2 is a diagram schematically showing an example configuration of an ion implantation apparatus according to an embodiment of the present disclosure.

FIG. 3 is a diagram schematically showing beam intensity changes in a slow scan direction which are monitored by a beam profiler of the ion implantation apparatus of the embodiment of the present disclosure.

FIG. 4A is a diagram showing a distribution in a chip surface of the saturation characteristic of the solid-state imaging device formed by the impurity implantation method of the embodiment of the present disclosure.

FIG. 4B is a diagram showing a distribution in a chip surface of the saturation characteristic of a solid-state imaging device which is formed by high energy ion implantation where a beam skirt portion has a steep profile, as a comparative example.

FIG. 5 is a flowchart showing an algorithm for determining a shape of an ion beam in the impurity implantation method of the embodiment of the present disclosure.

FIGS. 6A-6C are diagrams each schematically showing a relationship between a scan pitch Ps and the ion beam shape, and a total dose due to beam overlapping.

FIG. 7 is a cross-sectional view schematically showing ion implantation which is performed in a direction normal to a silicon substrate using a resist mask having an opening for ion implantation, where the opening has a tapered sidewall.

FIG. 8 is a cross-sectional view schematically showing ion implantation which is performed using a resist mask having an opening for ion implantation, where the opening has a vertical sidewall and there are variations in the incident direction of ions.

FIG. 9 is a diagram schematically showing ion implantation including a fast scan with a fast scan speed and a slow scan with a slow scan speed.

### DETAILED DESCRIPTION

### Embodiment

An impurity implantation method and an ion implantation apparatus according to an embodiment of the present disclosure will be described hereinafter with reference to the accompanying drawings.

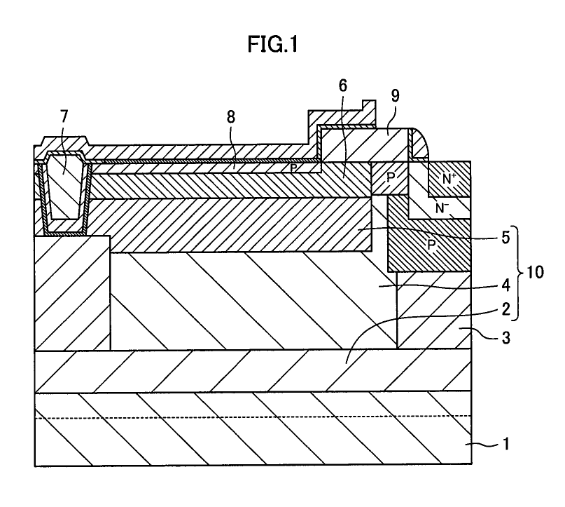

FIG. 1 is a cross-sectional diagram schematically showing a structure of an example solid-state imaging device to which the impurity implantation method of this embodiment is applied.

The solid-state imaging device of FIG. 1 is, for example, formed on an N-type epitaxial layer 4 having a thickness of about 10 μm which is formed on an N-type silicon substrate 1. The specific resistance of the epitaxial layer 4 is, for example, 30 Ω·cm. For example, a P-type B (boron) implantation layer 6 is formed in an upper portion of the epitaxial layer 4, and an N-type As (arsenic) implantation layer 5 is formed in the epitaxial layer 4 below the B implantation layer 6 by high energy ion implantation. Further, for example, a P-type B implantation layer 2 is formed in the lower portion of the epitaxial layer 4 by high energy ion implantation. The P-type B implantation layer 2 and the N-type As implantation layer 5, which sandwich the low-concentration N-type epitaxial layer 4, constitute a photodiode 10 which is a pixel. A transfer gate 9 for transferring electric charge is formed on the B implantation layer 6, and for example, a high-concentration P-type surface layer 8 is formed in a region of an uppermost surface portion of the B implantation layer 6 which does not overlap the transfer gate 9. In the epitaxial layer 4, for example, an isolation region 7 having a shallow trench isolation (STI) structure and a P-type isolation region 3 are formed with the photodiode 10 being interposed therebetween. The P-type isolation region 3 is formed by high energy ion implantation. The P-type B implantation layer 2, which is a lower portion of the photodiode 10, is connected to the P-type isolation region 3.

The impurity implantation method of this embodiment will be described hereinafter, for example, in a case where the P-type B implantation layer 2 (photodiode region), which is located at a deepest position of the epitaxial layer 4, is formed by high energy ion implantation.

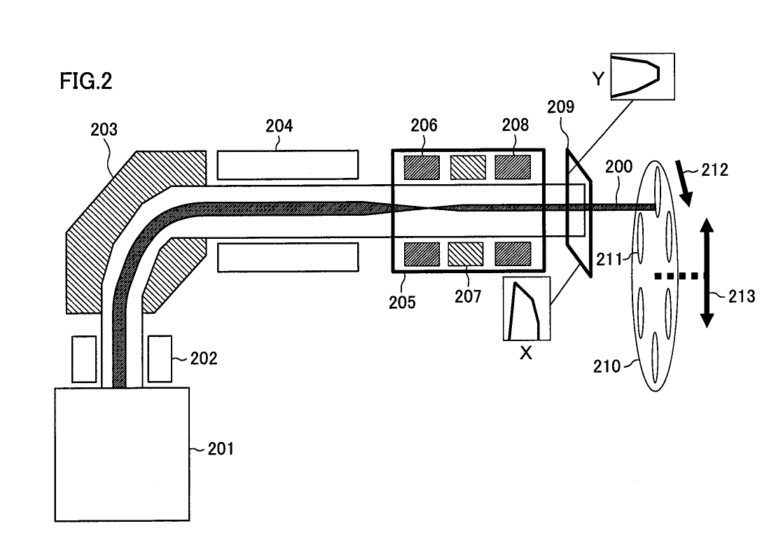

FIG. 2 is a diagram schematically showing an example configuration of a high energy ion implantation apparatus (i.e., an ion implantation apparatus according to this embodiment) which employs the impurity implantation method of this embodiment.

As shown in FIG. 2, the ion implantation apparatus of this embodiment includes a disk 210 (rotating member) which allows an ion beam 200 to be two-dimensionally scanned over a wafer (semiconductor substrate) 211 (object to be processed). Here, a plurality of (e.g., thirteen) wafers 211 each having a diameter of, for example, 300 mm are provided on the disk 210 along the outer circumference thereof. The distance between the center of each wafer 211 and the center of the disk 210 is, for example, 750 mm. By the disk 210 performing rotation 212, the ion beam 200 can be scanned over each wafer 211 in a fast scan direction at a first scan speed. Specifically, if it is assumed that the rotational speed of the rotation 212 is, for example, 815 rpm, the linear velocity (i.e., the first scan speed) of the rotation 212 at the center of each wafer 211 is 64 m/sec. In this case, the frequency (per sec) of the rotation 212 of the disk 210 is 13.6 Hz. On the other hand, the disk 210 performs reciprocal movement 213, whereby the ion beam 200 can be scanned over each wafer 211 in a slow scan direction at a second scan speed which is lower than the first scan speed. Specifically, the disk 210 is moved back and forth across a distance of, for example, 320 mm at a speed of 1 cm/sec. In this case, the scan pitch of the slow scan with respect to the fast scan is 1 cm/sec÷13.6 Hz=0.74 mm.

Note that, in this embodiment, the ion beam 200 has a beam size which is defined by the size of a portion of the beam which has 80% or more of the maximum beam current value. In this case, the beam size of the ion beam 200 is, for example, 20 mm. Thus, while the beam size is 20 mm, the scan pitch is 0.74 mm.

A feature of the ion implantation apparatus of this embodiment is that a beam shape (beam intensity change) of the ion beam 200, even including a beam skirt portion thereof, can be controlled. Specifically, as shown in FIG. 2, in the ion implantation apparatus of this embodiment, ions are extracted from an ion source 201 by an ion extractor 202, passed through a mass analyzer 203, and accelerated and output as the ion beam 200 by an accelerator 204. While an ion beam output from an accelerator is typically allowed to directly reach a wafer in the conventional art, the ion beam 200 output from the accelerator 204 is introduced into a defocusing unit 205 before reaching a wafer in the ion implantation apparatus of this embodiment.

In the defocusing unit 205, the ion beam 200 is converged by a converging lens 206 so that the beam size thereof becomes, for example, 20 mm, and thereafter, the ion beam 200 is diverged and expanded by a diverging lens 207 provided downstream from the converging lens 206 so that the beam size thereof temporarily becomes about 30 mm. Thereafter, the irradiation angle (incident angle) with respect to the wafer 211 of ions of the ion beam 200 expanded by the diverging lens 207 is controlled by a control lens (e.g., a converging lens 208) which is provided downstream from the diverging lens 207.

As described above, in the ion implantation apparatus of this embodiment, the ion beam 200 can be only blurred (beam defocusing), without changing the incident angle of the ions, by the converging lens 206, the diverging lens 207, and the converging lens 208 provided in the defocusing unit 205.

Another feature of the ion implantation apparatus of this embodiment is that shapes in the fast scan direction (X-direction) and the slow scan direction (Y-direction) of the ion beam 200, even including a beam skirt portion thereof, can be monitored using a beam profiler 209 provided downstream from the defocusing unit 205. The information acquired by the beam profiler 209 is fed back to the defocusing unit 205. As a result, in this embodiment, the shape of the ion beam 200, particularly the shape of the beam skirt portion, can be controlled into a desired shape by the defocusing unit 205 and the beam profiler 209 repeatedly performing the beam defocusing and the beam shape monitoring, respectively.

It is assumed that divalent boron ions (B⁺⁺) are implanted into the wafer 211 using a resist film having a thickness of, for example, about 5 μm as a mask, where, for example, the acceleration energy is 3 MeV and the tilt angle (incident angle) with respect to the normal direction of the principal surface of the wafer 211 is zero degrees. In this case, although the incident angle of a center portion of the ion beam 200 after passing through the diverging lens 207 remains zero degrees, a skirt portion of the ion beam 200 extends outward. Therefore, the most downstream converging lens 208 is used to control the incident angle of the ion beam 200 including the skirt portion so that the incident angle falls within, for example, 0±0.5°. Note that B⁺⁺ having an acceleration energy of 3 MeV has an Rp (average range) of 3.83 μm and a ΔRp (1σ of Rp) of 0.2134 μm, and therefore, the resist film having a thickness of 5 μm can provide a sufficient mask effect. The extension of the ions due to the angle error of ±0.5° is about 77 nm in Si in which B⁺⁺ has an Rp of 3.83 μm, and is thus sufficiently smaller than the ΔRp (=0.2134 μm) of the ion beam itself. This proves the validity of the control which allows the incident angle to fall within 0±0.5°.

The control of the beam shape (beam intensity change) of the beam skirt portion by the defocusing unit 205 in the ion implantation apparatus of this embodiment will be described hereinafter in greater detail.

A feature of this embodiment is that an intensity change rate at a position in the intensity profile of the ion beam 200 where the intensity is 50% of the maximum intensity is controlled to satisfy the following relationship:

Ps<Imax/S50 (1)

where Imax is the maximum intensity of the ion beam 200, S50 is the intensity change rate at the aforementioned position of the ion beam 200, and Ps is the scan pitch in the slow scan direction (Y-direction).

In other words, the intensity change rate S50 is controlled to satisfy the following relationship derived from expression (1):

S50<Imax/Ps (2)

Because Imax/S50 on the right-hand side of expression (1) is an intensity profile width at the intensity change rate S50, expression (1) means that if the scan pitch Ps is smaller than the intensity profile width at the intensity change rate S50, the uniformity of the implantation dose, the implantation depth, and the like is improved. Conversely, expression (2) means that if the intensity change rate S50 is decreased (i.e., the shape of the beam skirt portion is broadened), the uniformity improving effect is obtained without decreasing the scan pitch Ps. Here, the implantation angle with respect to the wafer 211 of ions in the ion beam 200 is controlled by the most downstream converging lens 208 to a predetermined angle (e.g., within 0±0.5°) over the entire ion beam 200. As a result, the extension of the impurity implanted region due to variations in the incident direction of ions in high energy ion implantation can be reduced.

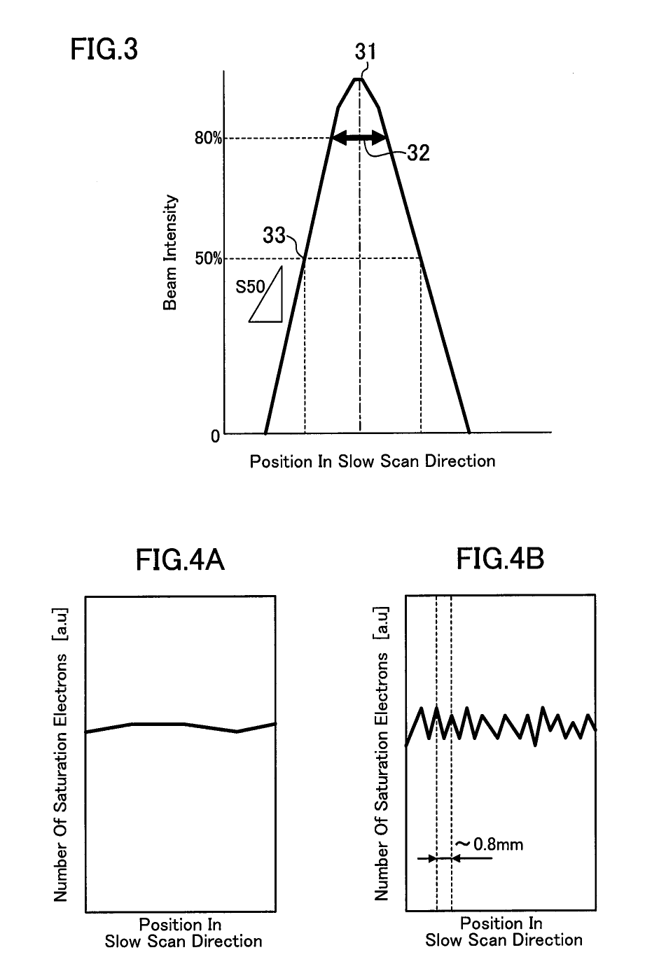

FIG. 3 is a diagram schematically showing beam intensity changes (beam intensity profile) in the slow scan direction (Y-direction) which are monitored by the beam profiler 209 of this embodiment. In FIG. 3, a reference character “31” indicates the maximum beam intensity Imax, and a reference character “32” indicates a beam width (beam size) which is defined by the size of a beam portion whose intensity is 80% or more of the maximum intensity Imax. Also, a reference character “33” indicates a point in the beam intensity profile where the intensity is 50% of the maximum intensity Imax and the intensity change rate is S50. Here, if it is assumed that the scan pitch Ps is, for example, 0.74 mm as described above and the maximum intensity Imax is, for example, 19 μA, it can be seen from expression (2) that the intensity change rate S50 needs to be smaller than 25.7 μA/mm. Therefore, in this embodiment, the defocusing unit 205 and the beam profiler 209 are used to control the intensity change rate S50 to 10 μA/mm. In this case, the beam size remains, for example, 20 mm.

Note that, as described above, the control of the shape of the ion beam 200, particularly the shape of the beam skirt portion, is performed by feeding back to the defocusing unit 205 the beam shape obtained by the beam profiler (X-Y beam profiler) 209 provided downstream from the defocusing unit 205. Also, in order to reduce or prevent variations in the dose and the like, the shape of the ion beam 200 needs to satisfy the relationship Ps<Imax/S50 of expression (1). Needless to say, the uniformity can be ensured by narrowing the scan pitch Ps. However, this unavoidably leads to a reduction in throughput, and therefore, is not suitable for practical use.

FIG. 4A is a diagram showing a distribution in a chip surface of the saturation characteristic of the solid-state imaging device of this embodiment which is formed by high energy ion implantation as described above. FIG. 4B is a diagram showing a distribution in a chip surface of the saturation characteristic of a solid-state imaging device which is formed by high energy ion implantation where the intensity change rate S50 is set to 50 μA/mm (i.e., the beam skirt portion has a steep profile), as a comparative example. Note that, in FIGS. 4A and 4B, the horizontal axis indicates positions in the Y-direction (slow scan direction) of the chip, and the vertical axis indicates the numbers of saturation electrons (in arbitrary units (a. u.)) at the center position in the X-direction (fast scan direction) of the chip.

As shown in FIG. 4A, in the solid-state imaging device of this embodiment which is formed by ion implantation using a defocused ion beam, variations in the number of saturation electrons are limited to small levels. However, as shown in FIG. 4B, in the solid-state imaging device of the comparative example which is formed by ion implantation using an ion beam whose beam skirt portion has the steep profile (the other scan conditions are the same as those of this embodiment), variations in the number of saturation electrons (non-uniform saturation) due to a mismatch between the ion beam shape and the scan pitch (0.74 mm) are observed. The non-uniform saturation is observed over the entire wafer and has a pitch substantially equal to the scan pitch. Moreover, in FIG. 4B, although only information at the center in the X-direction of the chip is plotted, the non-uniform saturation is observed as a striped pattern in the Y-direction in images obtained by the imaging device.

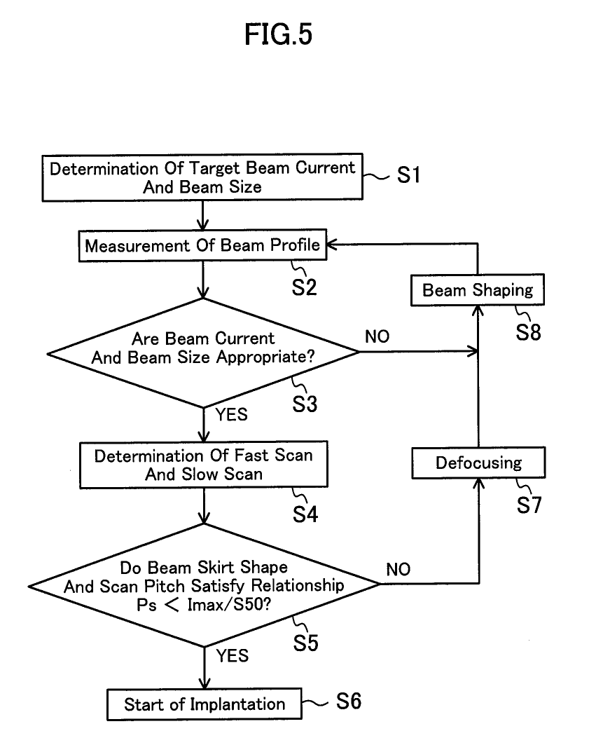

FIG. 5 is a flowchart showing an algorithm for determining the shape of an ion beam in the impurity implantation method of this embodiment.

As shown in FIG. 5, initially, in step S1, a target beam current and beam size are determined for a requested dose and uniformity.

Next, in step S2, the beam shape is measured using the beam profiler 209. Thereafter, in step S3, it is determined whether or not the target beam current and beam size have been obtained. When the determination is negative, beam shaping is performed in step S8, and thereafter, step S2 and the subsequent steps are repeated.

When the determination is positive in step S3, the speed of the fast scan and the speed of the slow scan are determined based on the beam profile obtained by the beam profiler 209 in step S4. In this embodiment, the speed of the fast scan is determined by the rotational speed of the disk 210, and therefore, typically has a fixed value (e.g., 815 rpm). Note that when the fast scan is performed electrostatically (i.e., using an electric field) or electromagnetically (i.e., using a magnetic field), the speed of the fast scan can be easily changed and can have a wide range within which it is changed. Therefore, even during scanning, if the beam profile is changed due to information from the beam profiler, the speed of the fast scan can be modulated to follow the change in the beam profile.

The speed of the fast scan is typically fixed because an ion implantation apparatus, such as that of this embodiment, which determines the speed of the fast scan by the disk rotation has a poor capability of tracking the scan speed due to the inertia of the disk as described above. In this case, a decrease in the speed of the slow scan leads directly to a reduction in the productivity. Therefore, if the speed of the slow scan needs to be slowed because the beam current value is low, tuning is performed again so as to improve the beam current value. Specifically, the dose and the uniformity are determined by the speed of the slow scan. If the beam current value is successfully improved, scanning is performed while maintaining the speed of the slow scan. If the beam current value fails to be improved, the speed of the slow scan is set to a low value. Here, instead of or in addition to slowing the speed of the slow scan itself, the number of round trips of the slow scan, i.e., the number of slow scans may be increased. When a large rotating disk is moved in the slow scan as in this embodiment, there is a limit of a change in the speed of the slow scan, and the speed of the slow scan is typically set to a relatively low speed. Therefore, the number of slow scans is adjusted in the conventional art. In this regard, in the ion implantation apparatus of this embodiment, the speed of the slow scan is 1 cm/sec, and a round-trip scan across a wafer having a diameter of 300 mm takes about 64 sec (the actual scan length is 320 mm because an oversew is performed across 10 mm at each of the opposite ends of the wafer).

Thus, when the beam current value is lower than a value corresponding to the requested dose or when the number of slow scans is insufficient for the uniformity, the number of slow scans is increased in the conventional art. Specifically, instead of only one round rip of the slow scan, two or more round trips of the slow scan may be performed. However, the number of slow scans can be increased when the beam current value is smaller than a value corresponding to a dose which can be implanted in two slow scans (i.e., one round trip). For example, assuming that the required dose is, for example, 5×10¹¹ cm⁻² in this embodiment, if the number of slow scans is two (one round trip), a beam current value which is required to achieve the dose of 5×10¹¹ cm⁻² is 19 μA, where the speed of the fast scan is 815 rpm, the speed of the slow scan is 1 cm/sec, and the beam size is 20 mm. Specifically, when the beam current value is larger than 19 μA, the speed of the slow scan needs to be increased to broaden the scan pitch. For example, if the beam current value is 38 μA, the speed of the slow scan needs to be set to 2 cm/sec. In this case, however, the scan pitch is increased from 0.74 mm (where the speed of the slow scan is 1 cm/sec) to 1.48 mm, and therefore, it is difficult to ensure the uniformity.

On the other hand, in order to cause the scan pitch to be narrower than 0.74 mm, the speed of the slow scan may be slowed. For example, when the speed of the slow scan is 0.33 cm/sec, the scan pitch is as narrow as 0.246 mm. In this case, the beam current value needs to be decreased to 6.3 μA, which is ⅓ of 19 μA. Also in this case, the number of fast scans is increased by a factor of 3, and therefore, the time required for ion implantation is increased by a factor of 3. Nevertheless, implantation can be more uniformly performed because of the narrower scan pitch of the ion beam. However, because it is difficult to generate an ion beam having such a low beam current value, the scan pitch cannot be narrowed unless an ion beam having a beam current value of 6.3 μA is stably obtained. Therefore, it is difficult to use a low beam current value with respect to a request for a low dose (specifically, 1×10¹² cm⁻² or less), and therefore, the number of slow scans often needs to be a minimum number (one), i.e., it is often that the scan pitch cannot be intentionally narrowed.

In contrast to this, in this embodiment, in step S5, the scan pitch Ps is calculated from the speed of the slow scan which is obtained with respect to the target beam current in step S4, and it is determined whether or not the scan pitch Ps satisfies the relationship Ps<Imax/S50 of expression (1), using the actual intensity change rate S50 of the beam skirt portion obtained by the beam profiler 209. If the relationship of expression (1) is not satisfied, in step S7 the intensity change rate S50 of the beam skirt portion is reduced using the defocusing unit 205 (particularly, the diverging lens 207 and the most downstream converging lens 208) so that the relationship of expression (1) is satisfied. In this case, if the beam size is changed, the speed of the slow scan, the beam current value, and the like need to be calculated again, and again in step S8, the beam shaping is performed, and thereafter, step S2 (measurement of the beam shape using the beam profiler 209) and the subsequent steps are repeated. When it is determined in step S5 that the relationship of expression (1) is satisfied, ion implantation is started under the determined scan conditions. For example, in the ion implantation of this embodiment employing the aforementioned scan conditions, the beam current value is 19 μA and the scan pitch is 0.74 mm, and therefore, the relationship of expression (2) is calculated as follows: S50<Imax/Ps=19/0.74=25.7 (μA/mm). On the other hand, in this embodiment, the intensity change rate S50 of the beam skirt portion is set to 10 μA/mm. Therefore, non-uniformity due to a mismatch between the ion beam shape and the scan pitch is not observed.

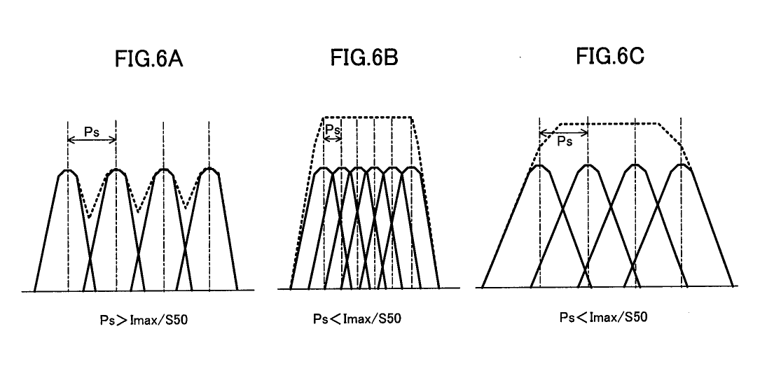

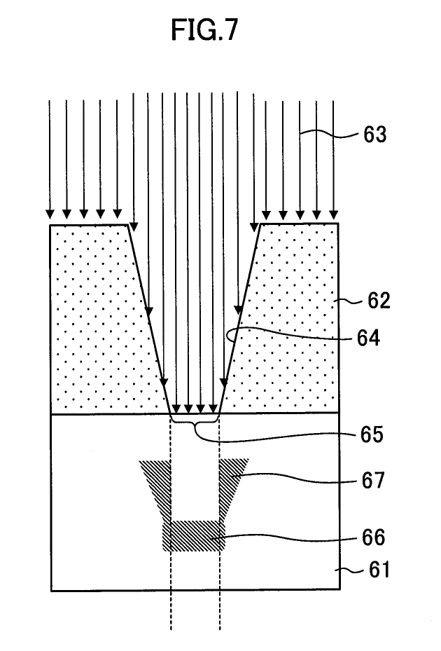

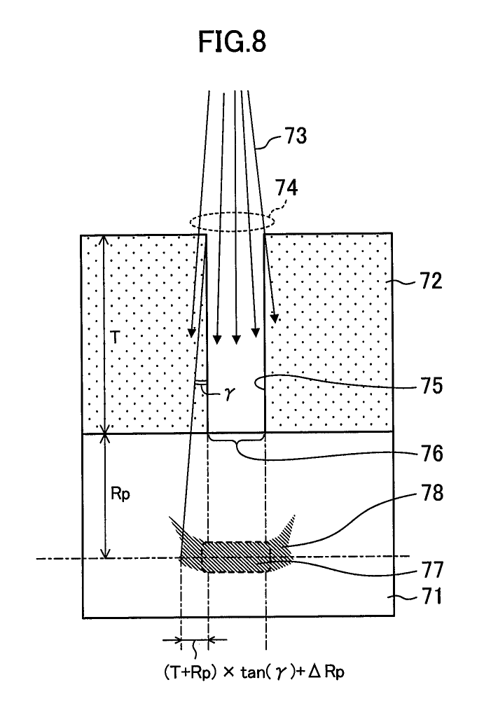

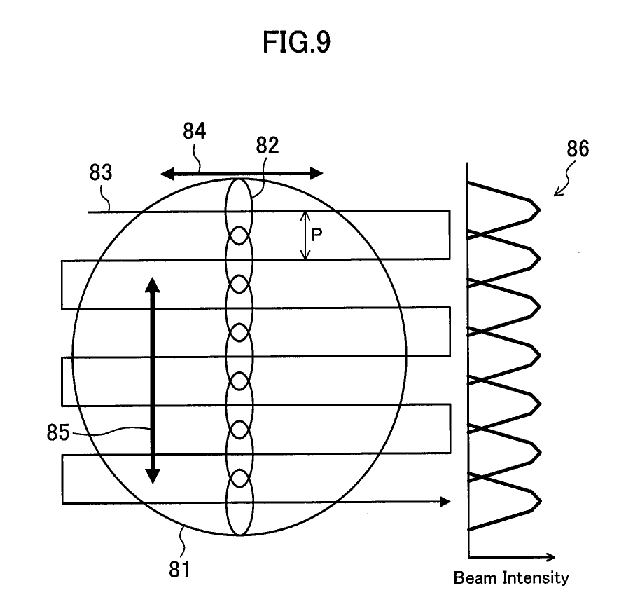

FIGS. 6A-6C are diagrams each schematically showing a relationship between the scan pitch Ps and the ion beam shape (i.e., the intensity change rate S50 of the beam skirt portion), and a total dose due to beam overlapping (indicated with a dotted line in the figures).

FIG. 6A shows a case where the relationship of expression (1) is clearly not satisfied (i.e., the scan pitch Ps is larger than Imax/S50). In this case, because a beam overlap, particularly an overlap at the beam skirt portion, is insufficient, the total dose undulates in periods of the scan pitch Ps.

FIG. 6B shows a case where the scan pitch Ps is narrowed while the same ion beam shape as that of FIG. 6A (i.e., a non-defocused ion beam shape) is maintained. As described above, the scan pitch Ps can be narrowed by decreasing the speed of the slow scan or increasing the number of slow scans. As a result, the relationship of expression (1) is satisfied, and therefore, as shown in FIG. 6B, the beam overlap is sufficient, resulting in an improvement in the uniformity. However, the productivity unavoidably decreases.

FIG. 6C shows a case where the relationship of expression (1) is satisfied by shaping and broadening the shape of the beam skirt portion while the same scan pitch Ps as that of FIG. 6A is maintained as in this embodiment. As shown in FIG. 6C, the beam intensity of the beam skirt portion has a gradual slope (low intensity change rate), and therefore, the uniformity can be improved by causing the beam skirt portions to overlap while the broad scan pitch Ps is maintained (i.e., without a decrease in the productivity).

As described above, according to this embodiment, ion implantation is performed using an ion beam which is diverged by, for example, the diverging lens 207 after being temporarily converged by, for example, the converging lens 206. Therefore, the beam shape, particularly the beam skirt shape having a large influence on the uniformity, can be controlled according to the scan pitch of the ion beam. Specifically, for example, by diverging and broadening the ion beam so that the relationship of expression (1) is satisfied, the uniformity of the implantation dose, the implantation depth, and the like can be improved without decreasing the scan pitch of the ion beam (or without increasing the number of scans). Therefore, even when the ion implantation is performed with high energy and a low dose, the uniformity can be improved without sacrificing the productivity. In other words, uniform ion implantation which does not depend on the scan pitch or the number of scans can be achieved.

Moreover, according to this embodiment, the implantation angle with respect to an object to be processed (e.g., a wafer) of ions in the diverged ion beam is controlled to a predetermined angle using, for example, the converging lens 208. As a result, the extension of the impurity implanted region due to variations in the incident direction of ions in high energy ion implantation can be controlled.

Moreover, compared to the conventional art, the aforementioned advantages of this embodiment are particularly significantly achieved when ion implantation is performed at an acceleration energy of 1 MeV or more and/or when the ion beam is a spot beam.

Here, when a spot beam is used, as the beam size is decreased, the number of scans is increased and therefore the non-uniformity due to beam overlapping is more likely to occur. Therefore, it is inappropriate to use a considerably converged beam for cases where charged particles need to be uniformly introduced to a plane, such as a wafer. Therefore, it is preferable to ensure a beam size which can be scanned over the entire wafer with a reasonable number of scans. For example, when the wafer has a diameter of 300 mm and the beam overlap is at least 50%, then if the beam size is 10 mm, scanning needs to be performed 60 times, resulting in a decrease in the productivity compared to this embodiment. Moreover, if the beam size is 10 mm, the scan pitch needs to be smaller than 0.74 mm of this embodiment.

On the other hand, if the beam size is increased, the number of scans can be reduced, resulting in an improvement in the productivity. For example, when a beam having an ultimate beam size, i.e., the same size (300 mm) as the diameter of the wafer, is used, it is no longer necessary to scan. At present, however, it is considerably difficult to form such a large beam, and it is also difficult to ensure the uniformity in such a large beam. Therefore, a so-called ribbon (band) beam having a width of, for example, about 300 mm in the fast scan direction and a width of, for example, 20 mm in the slow scan direction has been put to practical use. However, also in the case of the ribbon beam, it is not easy to ensure the uniformity in the fast scan direction which is the direction of the longer side. In addition, in the case of the ribbon beam, although the fast scan is not required, the slow scan is still required, and therefore, the problems of the present disclosure still exist. In other words, even when the ribbon beam is used, beam overlapping occurs in the slow scan direction, and therefore, the advantages of the present disclosure can be obtained.

In view of the foregoing, in this embodiment, a beam having a diameter which is larger than or equal to about 10 mm and is smaller than or equal to at least about ⅕ of the wafer diameter (about 60 mm when the wafer has a diameter of 300 mm) is regarded as a spot beam. Of course, a beam having a diameter of 80 mm may be regarded as a spot beam. However, the convergence capability of a beam (ions have a uniform direction), which is an advantage of spot beams, becomes worse as the beam size is increased. Therefore, beams having a diameter larger than about 60 mm are not regarded as spot beams in this embodiment.

Note that, in this embodiment, an example has been described where high-energy and low-dose ion implantation, in which micro-non-uniformity due to the scan pitch is likely to occur, is performed using boron (B) as the ion species. However, the ion species is not limited to boron. Needless to say, when an ion species, such as arsenic (As), phosphorus (P), or the like, is used, advantages similar to those of this embodiment can be obtained. Also, needless to say, advantages similar to those of this embodiment can be obtained irrespective of the valence of the ion species. Moreover, not only when low-dose ion implantation is performed, but also when ion implantation having a large ion current value is performed and short-time annealing (e.g., millisecond annealing, etc.) is performed, the micro-non-uniformity due to the scan pitch occurs. Also in such a case, advantages similar to those of this embodiment can be obtained by using an impurity implantation method and an ion implantation apparatus similar to those of this embodiment.

Moreover, in this embodiment, an example has been described in which a P-type well region 2 located at a deepest region of the epitaxial layer 4 is formed by high energy ion implantation as shown in FIG. 1. However, the present disclosure is not limited to this. By applying an impurity implantation method and an ion implantation apparatus similar to those of this embodiment to formation of a photodiode of a solid-state imaging device, formation of a deep impurity diffusion layer of a high breakdown voltage device, and the like, non-uniform saturation, non-uniform sensitivity, and the like can be reduced in the solid-state imaging device, and variations in the breakdown voltage, and the like can be reduced in the high breakdown voltage device, i.e., the performance of these devices can be improved. Moreover, by applying an impurity implantation method and an ion implantation apparatus similar to those of this embodiment to a case where a pattern made of a photoresist or a hard mask and having an opening is formed on a semiconductor substrate or a semiconductor layer, and an impurity is implanted through the opening into the semiconductor substrate or the semiconductor layer, an impurity layer having small variations in the implantation dose, the implantation depth, and the like can be reliably formed at a deep position below a surface of the semiconductor substrate or the semiconductor layer.

Moreover, although, in this embodiment, an example has been described where an ion beam is two-dimensionally scanned over an object to be processed, advantages similar to those of this embodiment can be obtained by applying an impurity implantation method and an ion implantation apparatus similar to those of this embodiment to other scanning manners in addition to such two-dimensional scanning. Moreover, advantages similar to those of this embodiment can be obtained by employing other two-dimensional scanning mechanisms in addition to rotating disks, such as that of this embodiment.

What is claimed is:

1. A method for implanting an impurity by ion implantation into an object to be processed, comprising:
performing the ion implantation using an ion beam which is diverged after being temporarily converged.

2. The method of claim 1, wherein
an implantation angle with respect to the object to be processed of ions in the diverged ion beam is controlled to a predetermined angle.

3. The method of claim 1, wherein
the object to be processed is a semiconductor substrate or a semiconductor layer,
a pattern made of a photoresist or a hard mask and having an opening is formed on the object to be processed, and
the impurity is implanted through the opening into the object to be processed.

4. The method of claim 1, wherein
the ion beam is two-dimensionally scanned over the object to be processed.

5. The method of claim 4, wherein
the ion beam is scanned in a fast scan direction at a first scan speed, and is scanned in a slow scan direction at a second scan speed lower than the first scan speed.

6. The method of claim 5, wherein
the object to be processed is placed on a rotating member,
the first scan speed is provided by rotation of the rotating member, and
the second scan speed is provided by reciprocal movement of the rotating member.

7. The method of claim 5, wherein
an intensity change rate at a position in a profile of an intensity of the ion beam where the intensity of the ion beam is 50% of a maximum intensity of the ion beam is controlled to satisfy a relationship given by:
Ps<Imax/S50
where Imax is the maximum intensity of the ion beam, S50 is the intensity change rate at the position of the ion beam, and Ps is a scan pitch in the slow scan direction.

8. The method of claim 7, wherein
an implantation angle with respect to the object to be processed of ions in the ion beam is controlled to a predetermined angle over an entire region of the ion beam.

9. The method of claim 1, wherein
the ion implantation is performed at an acceleration energy of 1 MeV or more.

10. The method of claim 1, wherein
the ion beam is a spot beam.

11. An apparatus for implanting an impurity by ion implantation into an object to be processed, comprising:
a defocusing unit including a converging lens configured to converge an ion beam and a diverging lens configured to diverge and expand the ion beam converged by the converging lens.

12. The apparatus of claim 11, wherein
the defocusing unit further includes a control lens configured to control an irradiation angle with respect to the object to be processed of ions in the ion beam expanded by the diverging lens.

13. The apparatus of claim 12, wherein
the control lens is another converging lens.

14. The apparatus of claim 11, further comprising:
a beam profiler provided downstream from the defocusing unit and configured to measure a shape of the ion beam.

15. The apparatus of claim 14, wherein
information obtained by the beam profiler is fed back to the defocusing unit.

16. The apparatus of claim 11, further comprising:
a mechanism configured to allow the ion beam to be two-dimensionally scanned over the object to be processed.

17. The apparatus of claim 16, wherein
the mechanism allows the ion beam to be scanned in a fast scan direction at a first scan speed and to be scanned in a slow scan direction at a second scan speed lower than the first scan speed, and
the apparatus further includes a beam profiler provided downstream from the defocusing unit and configured to measure a shape of the ion beam, including a skirt portion thereof, in the fast scan direction and in the slow scan direction.

18. The apparatus of claim 17, wherein
information obtained by the beam profiler is fed back to the defocusing unit.

19. The apparatus of claim 17, wherein
the mechanism includes a rotating member on which the object to be processed is placed,
the first scan speed is provided by rotation of the rotating member, and
the second scan speed is provided by reciprocal movement of the rotating member.

20. The apparatus of claim 11, wherein
the ion implantation is performed at an acceleration energy of 1 MeV or more.

21. The apparatus of claim 11, wherein
the ion beam is a spot beam.
